(19) United States
(12) Patent Application Publication
(10) Pub. No.: US 2004/0200405 A1
(43) Pub. Date: Oct. 14, 2004

(54) Crystallization method

(76) Inventors: Keita Sakai, Tochigi (JP); Nobukazu Yogo, Tochigi (JP)

Correspondence Address: MORGAN & FINNEGAN, L.L.P., 3 WORLD FINANCIAL CENTER, NEW YORK, NY, 10281-2101, US

(21) Appl. No.: 10/819,874

(22) Filed: Apr. 7, 2004

(30) Foreign Application Priority Data
Apr. 9, 2003 (JP) 2003-104797

(51) Int. Cl. C30B 9/00; C30B 21/02; C30B 11/00; C30B 17/00; C30B 28/06

(52) U.S. Cl. 117/81; 117/83

(57) ABSTRACT

A crystallization method includes the steps of producing a purified article made of a material as crystalloid by mixing with scavenger, melting, and then solidifying the material, inspecting an amount of remaining oxygen contained in the purified article, and melting the purified article selected by the inspecting step, and then growing crystal from the purified article.

This application claims a benefit of foreign priority based on Japanese Patent Application No. 2003-104797, filed on Apr. 9, 2003, which is hereby incorporated by reference herein in its entirety as if fully set forth herein.

### BACKGROUND OF THE INVENTION

The present invention relates generally to a crystallization or crystal manufacture method, and more particularly to a crystallization method for calcium fluoride (“CaF₂”) crystal as a material suitable for various optical elements, lenses and an exposure apparatus for use with a short wave range of a vacuum ultraviolet (“VUV”) to a far UV (“FUV”) light.

Recent demands for smaller and thinner-profile electronic devices have increased demands for finer semiconductor devices to be mounted onto these electronic devices. Various proposals have been made to improve the exposure resolution and satisfy this requirement. Shortening the wavelength of an exposure light is one effective solution for improved resolution, and a light source has recently been in transition from KrF excimer laser (with a wavelength of approximately 248 nm) to ArF excimer laser (with a wavelength of approximately 193 nm). A F₂ excimer laser (with a wavelength of approximately 157 nm) is nearly reduced to practice.

Most glass materials, however, are unsuitable for light sources with short wavelength due to insufficient transmittance. Quartz glass (“SiO₂”), barely available for the ArF excimer laser's wave range, is unusable in the F₂ laser's wave range. Thus, an optical system could only be made of CaF₂ crystal. Therefore, to improve its performance, an exposure apparatus utilizing an ArF excimer laser or F₂ laser as a light source, will indispensably require high-quality CaF₂ crystal.

Parameters for evaluating optical materials involve internal transmittance, laser durability indicative of a change in transmittance in response to continuous laser irradiations, refractive index homogeneity indicative of the degree of uniformity of a lens's refractive index depending upon positions, birefringence, workability or grinding performance, etc. CaF₂ crystal used for an exposure apparatus should possess high qualities in these aspects. For example, low internal transmittance leads to insufficient light intensity because exposure light attenuates before reaching a wafer. Laser-beam absorptions would cause temperature rises and refractive-index variances, resulting in deteriorations of imaging performance. Thus, because the low internal transmittance would deteriorate the throughput and imaging performance, CaF₂ crystals are required to have high internal transmittance, for example, more than 99% per 10-millimeter thickness.

Importantly, impurities in CaF₂ should be eliminated as much as possible so as to provide CaF₂ crystals with high internal transmittance. It is known that remaining rare earth, such as yttrium and cerium, and transition metals, such as iron and manganese, lowers the internal transmittance and transmittance in response to the laser irradiations (or laser durability). Currently, a material stage can successfully eliminate these impurities and minimize the decrease of internal transmittance caused by the rare earth and transition metals.

However, even when impurities are sufficiently eliminated in the material stage, other impurities, such as water-induced oxidized CaF₂, and residual scavenger added for anti-oxidation purposes are introduced by the manufacture stage. It is known that oxidation or residual oxygen causes significant absorptions in wave ranges below 160 nm, while residual lead fluoride and zinc fluoride, usually used as scavengers, lower internal transmittance and laser durability. To obtain excellent internal transmittance and laser durability, it is important to provide sufficient reduction reactions for anti-oxidation and to control a critical mass of added scavenger for reduced residual.

Process control for inspecting any remaining oxygen or scavenger in the manufacture step should also be considered. CaF₂ crystals for an exposure apparatus are generally manufactured in three steps, i.e., the purification step involves purifying a material to improve its volume density and eliminate impurities, the growth step involves growing the final crystal using, as a secondary material, a CaF₂ block prepared by the purification step, and an annealing step for removing strain from the CaF₂ crystallized in the growing step. All three steps use scavengers, which can result in oxidations and scavenger residuals, and require inspections of oxidations and scavenger residuals between steps. The annealing step for improving the homogeneity may be omitted depending on the applications, or may continue in a growth furnace after the growth step. In these occasions, no inspection is needed between the growing step and the annealing step, when there is an inspection between the purification step and the growing step.

Various approaches using elemental analysis have been proposed as an inspection of oxygen and remaining scavenger between steps. See, for example, Japanese Patent Applications, Publication Nos. 2000-119079, 2000-119098, 2001-072495 and 2002-255687. These approaches' process controls exercise a quantitative analysis to a metal element in the scavenger, between steps. For example, for the scavenger that uses lead fluoride, the lead quantitative analysis is exercised between the steps for control within a predetermined concentration. The process control that exercises the quantitative analysis to impurities provides stable manufactures of CaF₂ crystal having excellent qualities, such as internal transmittance and laser durability.

The quantitative analysis is, however, disadvantageously time-consuming and costly. The quantitative analysis that utilizes Inductively Coupled Plasma—Mass Spectrometer (“ICP-MS”), or Inductively Coupled Plasma Atomic Emission Spectrometer (“ICP-AES”) is expensive in machine installations or analytical commissions to an external institution. Before analyzed, a sample should be reduced to powder and liquidized and time problems increase for analyses of many samples. On the other hand, time and cost problems would reduce with a comparatively simple analytical method, such as a fluorescent X-ray analysis, but the process control becomes insufficient since this method cannot provide an accurate quantitative analysis to a small amount of impurities.

Disadvantageously, the quantitative analysis cannot determine whether there is oxidation. Each step may result in scavenger residuals or oxidation due to lack of scavenger. In this case, oxidation would possibly lower the transmittance and laser durability even when a metal element is not detected. Any introduced quantitative analysis of a small amount of oxygen would not detect oxygen accurately even when it utilizes a combustion method, a radiochemical analysis, or a Secondary Ion Mass Spectrometer (“SIMS”).

### BRIEF SUMMARY OF THE INVENTION

Accordingly, it is an exemplary object of the present invention to provide a crystallization method, which can stably manufacture crystal having excellent qualities, such as internal transmittance and laser durability.

A crystallization method of one aspect according to the present invention includes the steps of producing a purified article made of a material as crystalloid by mixing with scavenger, melting, and then solidifying the material, inspecting an amount of remaining oxygen contained in the purified article, and melting the purified article selected by said inspecting step, and then growing crystal from the purified article. The crystalloid may be calcium fluoride.

A crystallization method of another aspect according to the present invention includes the steps of producing a purified article made of a material as crystalloid by mixing with scavenger, melting, and then solidifying the material, measuring transmittance in the purified article produced by said producing step to a predetermined wavelength, and selecting the purified article having predetermined transmittance, and melting the purified article having the predetermined transmittance selected by said selecting step, and then growing crystal from the purified article. The predetermined wavelength may be between 100 nm and 300 nm. The predetermined transmittance may be 80% is greater per 10-millimeter thickness when normalized by setting transmittance to light having a wavelength of 200 nm to be 100%.

A crystallization method of still another aspect according to the present invention includes the steps of producing a purified article made of a material as crystalloid by mixing with scavenger, melting, and then solidifying the material, measuring the decrease of transmittance in the purified article produced by said producing step after irradiating a predetermined energy ray onto the purified article, and selecting the purified article that has the decrease of transmittance in a predetermined range, and melting the purified article having the predetermined transmittance selected by said selecting step, and then growing crystal from the purified article.

The predetermined energy ray may be F₂ laser, ArF excimer laser, X-ray or γ-ray. The decrease of transmittance within the predetermined range may be 2% or smaller per 10-millimeter thickness in a wave range between 150 nm and 800 nm when F₂ laser having an energy density of 10 mJ/cm² per pulse is irradiated with 10⁵ pulses or greater. The decrease of transmittance within the predetermined range may be 10% or smaller per 10-millimeter thickness in a wave range between 200 nm and 900 nm when γ-ray of 10⁵ R /hour is irradiated for one hour.

A crystallization method of still another aspect according to the present invention includes the steps of producing a purified article made of a material as crystalloid by mixing with scavenger, melting, and then solidifying the material, measuring fluorescent intensity emitted from the purified article produced by said producing step after irradiating ultraviolet light onto the purified article, and selecting the purified article that has predetermined fluorescent intensity; and melting the purified article having the predetermined fluorescent intensity selected by said selecting step, and then growing crystal from the purified article.

The ultraviolet light may be F₂ laser or ArF excimer laser. The predetermined fluorescent intensity may be relative intensity of 5 or smaller to fluorescent light having a wavelength of 370 nm, relative intensity of 2 or smaller to fluorescent light having a wavelength of 225 nm, and relative intensity of 1 or smaller to fluorescent light having a wavelength of 490 nm, where normalized by setting intensity of fluorescent light which has a wavelength of 280 nm to be 1 when F₂ laser having an energy density of 10 mJ/cm² per pulse is irradiated.

A crystallization method of another aspect according to the present invention includes the steps of melting a purified article produced from a material as crystalloid, and then growing crystal made of the material, inspecting an amount of remaining oxygen contained in the crystal grown in said growing step, and gradually cooling the crystal after the crystal selected by said inspecting step is processed at high temperature above 1000° C.

A crystallization method of another aspect according to the present invention includes the steps of melting a purified article produced from a material as crystalloid, and then growing crystal made of the material, measuring transmittance in the crystal grown by said growing step to a predetermined wavelength, and selecting the crystal having predetermined transmittance, and gradually cooling the crystal after the crystal having the predetermined transmittance selected by said selecting step is processed at high temperature above 1000° C.

A crystallization method of another aspect according to the present invention includes the steps of melting a purified article produced from a material as crystalloid, and then growing crystal made of the material, measuring the decrease of transmittance in the crystal after irradiating a predetermined energy ray onto the crystal grown by said growing step, and selecting the crystal having the decrease of transmittance in a predetermined range, and gradually cooling the crystal after the crystal having the predetermined transmittance selected by said selecting step is processed at high temperature above 1000° C.

A crystallization method of another aspect according to the present invention includes the steps of melting a purified article produced from a material as crystalloid, and then growing crystal made of the material, measuring fluorescent intensity emitted from the crystal grown by said growing step after irradiating ultraviolet onto the crystal, and selecting the crystal having the predetermined fluorescent intensity, and gradually cooling the crystal after the crystal having the predetermined transmittance selected by said selecting step is processed at high temperature above 1000° C.

An optical element of another aspect according to the present invention made of a single crystal, said single crystal being manufactured by any one of the above crystallization methods. The optical element may be a lens, a diffraction grating, an optical film or a combination thereof. For example, it may include a lens, a multi-lens, a lens array, a lenticule lens, a fly-eye lens, an aspheric lens, a diffraction grating, a binary optics element or a combination thereof. The optical element includes, for example, an optical sensor in addition to a single lens (e.g., for use with focus control).

An exposure apparatus of another aspect according to the present invention includes an optical system that includes an optical element made of single crystal manufactured by any one of the above crystallization methods.

claims for a device fabricating method for performing operations similar to that of the above exposure apparatus cover devices as intermediate and final products. Such devices include semiconductor chips like an LSI and VLSI, CCDs, LCDs, magnetic sensors, thin film magnetic heads, and the like. The exposure light may use ultraviolet light, far ultraviolet light, and vacuum ultraviolet light as exposure light.

Other objects and further features of the present invention will become readily apparent from the following description of the preferred embodiments with reference to accompanying drawings.

### BRIEF DESCRIPTION OF THE DRAWINGS

FIG. 1 is a schematic block diagram of a purification furnace used for a purification step for purifying a material of crystalloid.

FIG. 2 is a graph showing an exemplary measurement result of spectral transmittance of a purified article.

FIG. 3 is a schematic block view of a growth furnace used for a growth step for growing crystal from the purified article made of the material of crystalloid.

FIG. 4 is a graph showing an exemplary measurement result of spectral transmittance of the crystal obtained by growing the purified article.

FIG. 5 is a graph showing an exemplary measurement result of spectral transmittance in the purified article, onto which F₂ laser has been irradiated.

FIG. 6 is a table of an exemplary evaluation result of crystal about decrease of transmittance subsequent to irradiations of the F₂ laser.

FIG. 7 is a schematic block diagram of an exemplary fluorescent measuring apparatus that measures fluorescent light emitted from the calcium fluoride crystal, onto which ultraviolet light is irradiated.

FIG. 8 is a graph showing an exemplary measurement result of fluorescent light emitted from the purified article, onto which the F₂ laser is irradiated.

FIG. 9 is a schematic block diagram of an exemplary fluorescent measuring apparatus that measures fluorescent light emitted from calcium fluoride crystal, onto which ultraviolet light is irradiated.

FIG. 10 is a graph showing an exemplary measurement result of fluorescent light emitted from the crystal grown from the purified article, onto which the F₂ laser is irradiated.

FIG. 11 is a schematic block diagram of an exposure apparatus as one aspect according to the present invention.

FIG. 12 is a flowchart for explaining a method for fabricating devices (semiconductor chips such as ICs, LSIs, and the like, LCDs, CCDs, etc.).

FIG. 13 is a detailed flowchart for Step 4 of wafer process shown in FIG. 12.

### DETAILED DESCRIPTION OF THE PREFERRED EMBODIMENTS

A description will be given of a crystallization method of one embodiment according to the present invention. In each figure, like elements are designated by the same reference numerals, and a description thereof will be omitted.

In providing a crystallization method, which can stably manufacture crystal having excellent qualities, such as internal transmittance and laser durability, the instant inventors have discovered a process control using a method other than a quantitative analysis of impurities, as a result of earnest studies of process control in the crystallization steps (i.e., purification step, growth step, anneal step, etc.).

A process control of a first method evaluates transmittance. It is known that CaF₂ that oxidizes or contains scavenger has lowered transmittance in a wave range between UV and VUV. Accordingly, the process control can detect and use only non-detective articles for the next step by evaluating the transmittance between steps.

Samples for an evaluation of transmittance may be a large-aperture actual article or a fragment cut out of the actual article. Advantageously, an evaluation of the transmittance of the large-aperture actual article does not require a fragment to be cut and maintains the article size. In addition, this evaluation is effective when the large-aperture actual article has a quality distribution. On the other hand, this evaluation requires polishing and grinding near a surface, greatly increasing the working load in comparison with no process control.

On the other hand, the evaluation of the transmittance of the cut fragment advantageously facilitates handling, and enables the samples to be stored for reevaluation just in case. A fragment's surface to be used may be a cleavage plane or a polished plane, and the cleavage plane advantageously does not need to be polished. In evaluating the transmittance of a cleavage plane sample, it is preferable to use a spectrophotometer that arranges an insertion position of the sample just prior to its integrating sphere.

Preferably, the transmittance is evaluated in a wave range between 120 nm and 300 nm, but a single wavelength, such as 135 nm, is usable as far as it is in the wave range. In particular, for a sample that has a polished surface and contains no bubbles, an evaluation of transmittance to the single wavelength is effective for shortened measurement time. However, most purified articles contain bubbles, and it is preferable to normalize the transmittance in the wave range below 300 nm by setting a long wavelength, such as 300 nm, to be 100%. This normalization can roughly distinguish the scattering losses due to bubbles from the internal absorption in CaF₂ crystal.

A process control of a second method evaluates the decrease of transmittance in response to an irradiation of a high-energy ray. It is known that CaF₂ that oxidizes or contains scavenger has lowered transmittances to UV light, such as ArF excimer laser and F₂ laser, X-ray and γ-ray lower. Accordingly, a process control can detect non-detective articles for the next step by evaluating the decrease of transmittance in response to the high-energy ray or, in other words, high-energy ray durability the transmittance between steps.

Similar to the samples for an evaluation of transmittance, samples for an evaluation of high-energy ray durability may be a large-aperture actual article or a fragment cut out of the actual article. It is preferable to evaluate a large-aperture actual article, particularly when the large-aperture actual article has such a performance distribution that the center portion more remarkably oxidizes and leaves scavenger than the peripheral. On the other hand, it is preferable to evaluate a fragment cut from the peripheral, when the large-aperture actual article does not exhibit a performance distribution or when the large-aperture actual article has such a performance distribution that the peripheral more remarkably oxidizes and leaves scavenger than the center portion. In particular, it is preferable use a spectrophotometer that arranges an insertion position of the sample just prior to the integrating sphere, because a measurement at the cleavage plane does not require polishing and reduces the inspection cost.

There are various evaluation approaches according to types of high-energy rays, but the simplest one is a method of measuring transmittance after irradiations of high-energy rays with a spectrophotometer. When high-energy ray is irradiated onto CaF₂ crystal with impurities, an absorption band appears in a wave range between 200 nm and 700 nm. On the other hand, CaF₂ crystal whose absorption band is not in the wave range between 200 nm and 700 nm does not reduce transmittance in a VUV region. A wavelength of 200 nm or greater may be the air as a measurement atmosphere, and shorten the measurement time, preferable for the process control that should evaluate many samples.

When a high-energy ray use UV laser, such as ArF excimer laser, F₂ laser and Ar₂ laser, the high-energy ray is irradiated onto a sample while the light intensities before and after the sample are measured and the decrease of transmittance can be evaluated based on a changing ratio. This directly evaluates the durability to exposure light actually used for a lens, and provides high reliability. However, this method requires polishing of a sample surface, making expensive introduction costs of this method and an evaluation apparatus, and the running of laser.

A process control of a third method evaluates fluorescent light emitted in response to the UV irradiations. It is known that the fluorescent light is observed when ArF excimer laser and F₂ laser are irradiated onto CaF₂ crystal, and the fluorescent characteristic provides estimations of oxidation and remaining scavenger in CaF₂. Accordingly, a process control can detect non-detective articles for the next step by evaluating fluorescent light spectrum from UV-excited light between steps.

Similar to the samples for an evaluation of transmittance, samples for an evaluation of high-energy ray durability may be a large-aperture actual article or a fragment cut from the actual article. It is preferable to evaluate a large-aperture actual article, particularly when the large-aperture actual article has such a performance distribution that the center portion more remarkably oxidizes and leaves scavenger than the peripheral. On the other hand, it is preferable to evaluate a fragment cut from the peripheral, when the large-aperture actual article does not exhibit a performance distribution or when the large-aperture actual article has such a performance distribution that the peripheral more remarkably oxidizes and leaves scavenger than the center portion. In particular, an evaluation of the fluorescent light can use a fluorescent peak or intensity peculiar to CaF₂ crystal to normalize other fluorescent peaks, and provides a highly precise evaluation to even the cleavage plane.

While an evaluation of the fluorescent light uses ArF excimer laser and F₂ laser, more information is generally available from F₂ laser as excited light. When F₂ laser is used as excited light, the oxidation tendency provides strong fluorescent peaks at wavelengths of 320 nm and 370 nm. Remaining lead in lead fluoride as scavenger provides fluorescent peak at the wavelength of 225 nm, while remaining zinc in zinc fluoride as scavenger provides fluorescent peaks at a wavelength of 490 nm or 225 nm. Since the exington fluorescent peak intrinsic to CaF₂ crystal appears at the wavelength of 280 nm, a stable evaluation is available irrespective of sample shapes when other fluorescent peaks are normalized by setting the fluorescent peak to a wavelength of 280 nm to be 1. It should be noted in measuring fluorescent light by changing the laser irradiation energy density that when the excited light is ArF excimer laser or F₂ laser, the fluorescent peak of the wavelength of 280 nm becomes stronger proportionate to a square of the irradiation energy density but other fluorescent peaks become stronger proportionate to the irradiation energy density.

This method has advantages in that a fragment of cleavage plane can provide sufficient fluorescent evaluations and the measurement time is short, although the laser increases introduction costs of an evaluation apparatus and its running cost.

Thus, evaluations of transmittance, durability to a high-energy ray and fluorescent light would assure sufficient process controls, and stably produce crystal having excellent qualities, such as internal transmittance and laser durability.

A detailed description will now be given of the present invention by way of inventive examples:

### EXAMPLE 1

A description will now be given of an example 1 characterized in that process control means evaluates transmittance.

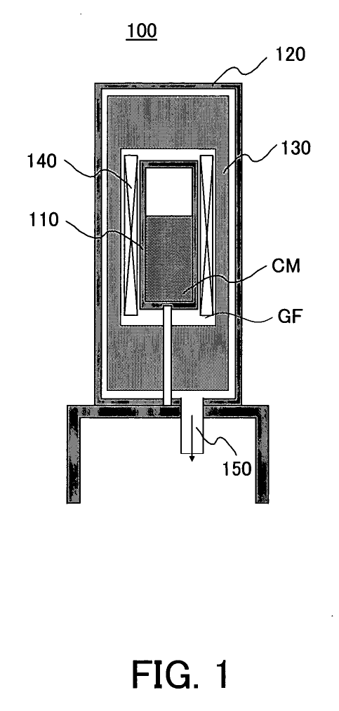

A material CM as CaF₂ powder was mixed with scavenger, and purified in a purification furnace 100 shown in FIG. 1. The purification furnace 100 includes a crucible 110 that houses the material CM, a furnace chamber GF that defines a chamber 120 and an insulator 130 and accommodates the crucible 110, and a heater 140 that heats up the crucible 110. Here, FIG. 1 is a schematic block diagram of the purification furnace 100 used for a purification step for purifying the material of crystalloid.

In operation, the purification furnace 100 uses an exhaust part 150 to maintain the furnace chamber GF at reduced pressure or vacuum, and the heater 140 to heat the material CM higher than a melting point between 1390° C. and 1450° C. to melt the material CM. Understandably, purified article which is a block of polycrystal is produced after the heater 140 stops heating and the melted material CM is cooled.

A cleavage article having a thickness of about 10 mm is taken out by partially crushing an end of the purified article. Here, the cleavage article is a fragment that forms two parallel surfaces with cleavage planes. The cleavage plane is more scratched than a usual polished surface, but applicable to a measurement of transmittance without hitch although it exhibits slight surface scattering.

After a surface of this cleavage article is cleansed with organic solvent, it is dry-cleansed, e.g., ozone-cleansed, and mounted on a spectrophotometer (not shown) compatible with measurements in a VUV wave range for transmittance measurements. The spectrophotometer (not shown) has an integral sphere, and arranges a surface of the cleavage article (sample) just prior to the integral sphere.

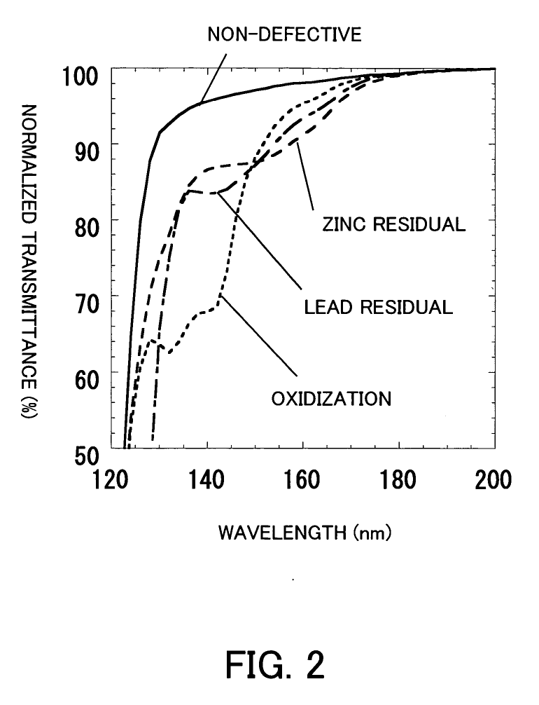

FIG. 2 shows an exemplary measurement result of the spectral transmittance in the cleavage article, where an abscissa axis is a wavelength between 120 nm and 200 nm, and an ordinate axis is normalized transmittance by setting the transmittance to a wavelength of 200 nm to be 100%. The normalization with the transmittance to the wavelength of 200 nm is to separates a scattering component from an absorption component. In particular, the purified article often contains bubbles, and the normalization provides better understanding. The normalized transmittance may use, for example, transmittance to a wavelength of 300 nm instead of the transmittance to a wavelength of 200 nm.

Referring to FIG. 2, the purified articles to be classified based on the transmittance into oxidized articles, lead remaining articles, zinc remaining articles, and non-defective articles. When the purified articles other than the non-defective articles are used for the subsequent growth step, the excellent transmittance cannot be obtained due to a succession of the property in the purification step. Therefore, it is important for process control to select the non-defective purified article and use only the selected non-defective purified article for the next growth step. An applied standard normalizes by setting the transmittance to the wavelength of 200 nm to be 100%, and regards a certain purified article as a non-defective purified one if it shows transmittance of 70% or greater, preferably 85% or greater per 10-millimeter thickness to the wavelength of 135 nm. However, this standard for the non-defective article is for illustrative purposes only, and a focused wavelength may be other than 135 nm. Of course, the. transmittance value is not limited to the above values. The best standard for the non-defective article can be set according to specifications required for CaF₂ crystal.

The above process control over purified articles evaluates transmittance, and stably manufactures crystal having excellent qualities, such as internal transmittance and laser durability.

### EXAMPLE 2

A description will now be given of an example 2 characterized in that process control means evaluates transmittance.

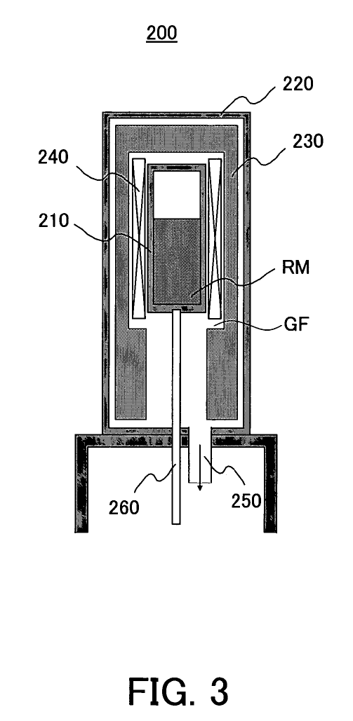

A block of purified article RM was mixed with scavenger, and subject to a crystal growth in a crystal growth furnace 200 shown in FIG. 3. The crystal growth furnace 200 includes an elevator mechanism 260 that supports a crucible 210 that houses the purified article RM so that the crucible 210 can go up and down, a furnace chamber GF that defines a chamber 220 and an insulator 230, and a heater 240 that heats up the crucible 210. The crystal growth furnace 200 further includes an exhaust part 250 that maintains the furnace chamber GF at reduced pressure or vacuum. Here, FIG. 3 is a schematic block diagram of the growth furnace 200 used for a growth step for growing crystal of a material of crystalloid.

In operation, the crystal growth furnace 200 uses the exhaust part 250 to maintain the furnace chamber GF at reduced pressure or vacuum, and the heater 240 to heat the purified article RM higher than the melting point between 1390° C. and 1450° C. to melt the purified article RM. Next, the elevator mechanism 260 descends the crucible 210 at a speed of about 0.1 to 5 mm /hour. Understandably, a single crystal gradually grows when the crucible 210 goes down to a position corresponding to the melting point of CaF₂.

After single crystal that has grown was taken out of the crucible 210, cut into a cylinder shape with a thickness of 50 mm, and polished at both surfaces thereof, its transmittance was measured with a spectrophotometer (not shown) that can measure high-aperture crystal.

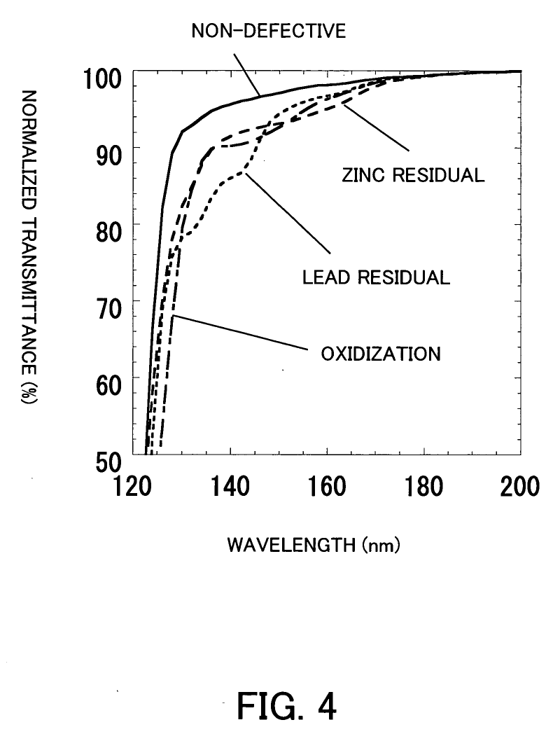

FIG. 4 is a graph showing an exemplary measurement result of spectral transmittance in the crystal obtained by growing the purified article, where an abscissa axis is a wavelength between 120 nm and 200 nm, and an ordinate axis is normalized transmittance by setting the transmittance to a wavelength of 200 nm to be 100%. Each measurement result was spectral transmittance obtained at one of five measurement points that includes four peripheral points and one center point in the crystal, which has the lowest transmittance.

Referring to FIG. 4, similar to the Example 1, the crystal to be classified based on the transmittance enables into oxidized articles, lead remaining articles, zinc remaining articles, and non-defective articles. The annealing step does not improve the transmittance deteriorated by oxidization and contamination. In other words, the annealing step cannot remove any cause of deterioration of internal transmittance and laser durability. Therefore, it is important for process control to select the non-defective crystal and use only the selected non-defective crystal for the next annealing step. An applied standard normalizes by setting transmittance to a wavelength of 200 nm to be 100%, and considers purified crystal to be non-defective as far as it has transmittance of 80% or greater, preferably 90% or greater per 10-millimeter thickness at a wavelength of 135 nm. However, this standard for the non-defective crystal is for illustrative purposes only, and a focused wavelength may be other than 135 nm. Of course, transmittance values are not limited to the above values. The best standard for the non-defective article can be set according to specifications required for CaF₂ crystal.

The above process control over purified articles thus evaluates transmittance, and stably manufactures crystal having excellent qualities, such as internal transmittance and laser durability.

### EXAMPLE 3

A description will now be given of an example 3 characterized in that process control means evaluates the decrease of transmittance in response to an irradiation of a high-energy ray.

A material CM as CaF₂ powder was mixed with scavenger, and purified into a purified article in the purification furnace 100 shown in FIG. 1 by melting the material at a high temperature and then cooling the same. An end of the purified article was partially crushed and taken out as a cleavage article having a thickness of about 10 mm.

This cleavage article was installed in the chamber for laser irradiations, and subject to irradiations of F₂ laser having an energy density of 10 mJ/cm² per pulse times 10⁶ pulses. After F₂ laser irradiations, the transmittance was measured with a UV/visual spectrophotometer. The UV/visual spectrophotometer has an integral sphere, and the cleavage article (sample) is located just before the integral sphere.

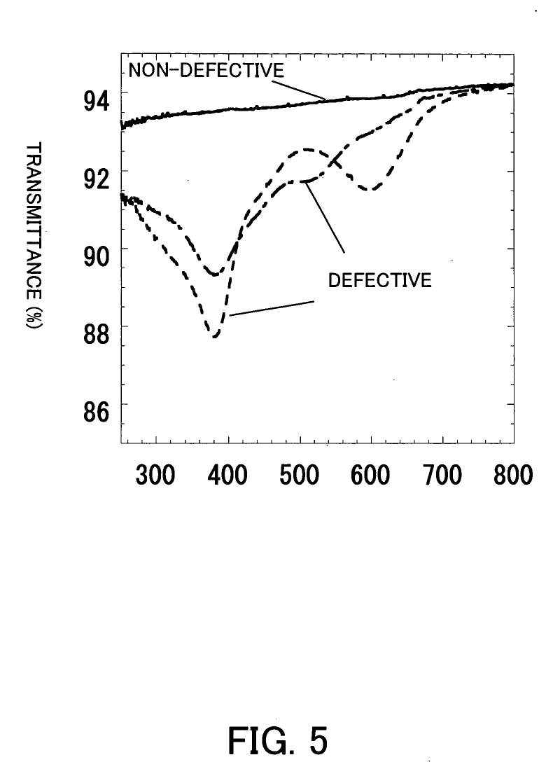

FIG. 5 shows an exemplary measurement result of spectral. transmittance in the cleavage article after F₂ laser irradiations, where an abscissa axis is a wavelength between 250 nm and 800 nm, and an ordinate axis is transmittance.

Referring to FIG. 5, the non-defective (purified) article hardly exhibits absorption bands even after irradiations of F₂ laser, but the defective (purified) article that appears to oxide or contain scavenger exhibits strong absorption peaks near wavelengths of 380 nm and 600 nm. When the purified article having lowered transmittance after the laser irradiations is used for the next growth step, the crystal grown by the growth step succeeds the property of the purified article by the purification step and cannot provide good transmittance. It is therefore important for the process control to select the non-defective purified articles and use only the selected non-defective purified articles for the growth step. An applied standard considers a purified article to be non-defective as far as it shows the decrease of transmittance per 10-millimeter thickness is 2% or smaller in a wave range between 250 nm and 800 nm after irradiations of F₂ laser having an energy density of 10 mJ/cm² per pulse times 10⁵ pulses. However, this standard for the non-defective article is for illustrative purposes only, and the type and condition of the irradiated energy ray are not limited to the above. Of course, the decrease of transmittance is not limited to the above value. The best standard for the non-defective article can be set according to specifications required for CaF₂ crystal. There is no definitive correlation between the decrease of the transmittance in response to the irradiations of F₂ laser and ArF excimer laser and the irradiated laser energy density. Since this correlation changes according to types and states of impurities in the purified article, it is preferable to determine an irradiation condition pursuant to the actual conditions where the CaF₂ crystal is used as a product.

Thus, the above process control over purified articles evaluates the decrease of transmittance through an irradiation of a high-energy ray, and stably manufactures crystal having excellent qualities, such as internal transmittance and laser durability.

### EXAMPLE 4

A description will now be given of an example 4 characterized in that process control means evaluates the decrease of transmittance in response to an irradiation of a high-energy ray.

A block of purified article RM was mixed with scavenger, and subject to a crystal growth in the crystal growth furnace 200 shown in FIG. 3. Single crystal gradually grew as the crucible 210 went down to cool after the purified article RM was melted at a high temperature. The grown single crystal was taken out of the crucible 210, cut into a cylinder shape having a thickness of 50 mm, and polished at both surfaces thereof. After the polished surfaces were cleansed, the spectrophotometer that could measure transmittance in large-aperture crystal was used to measure the transmittance to a wavelength of 157 nm.

This crystal was installed in the chamber for laser irradiations, and subject to irradiations of F₂ laser having an energy density of 10 mJ/cm² per pulse times 10⁶ pulses at five points including four peripheral points and one center point in the crystal. The spectrophotometer that could measure transmittance in large-aperture crystal was used to measure the transmittance to light having a wavelength of 157 nm again.

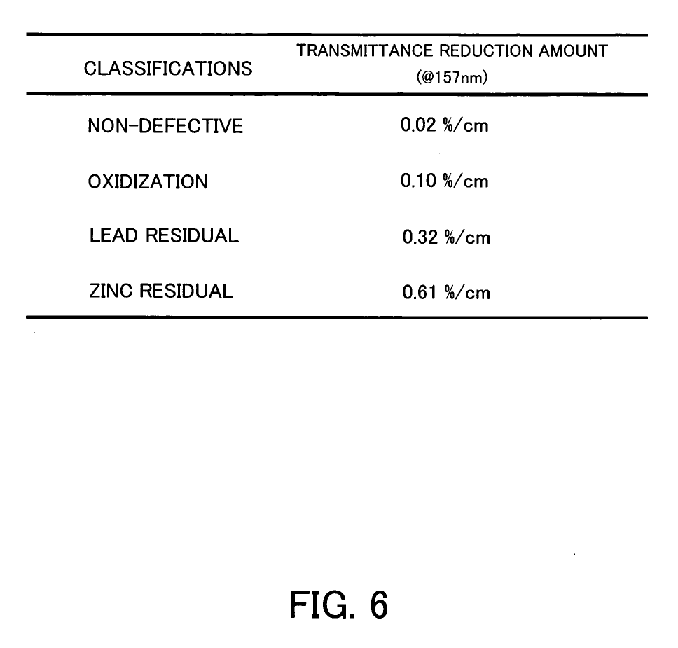

FIG. 6 shows an exemplary evaluation result of the decrease of transmittance to a wavelength of 157 nm in crystal having a converted thickness of 10 mm after irradiations of F₂ laser.

Referring to FIG. 6, it is understood that the non-defective crystal hardly lowers the transmittance, whereas the crystal that oxides or contains scavenger lowers transmittance. When the crystal other than the non-defective (which lowers transmittance after the laser irradiations) is used for the next annealing step, the annealing step does not improve the transmittance and cannot provide crystal having excellent qualities, such as internal transmittance and laser durability. Therefore, it is important for the process control to select the non-defective crystal and use only the selected non-defective purified crystal for the annealing step. An applied standard considers crystal to be non-defective as far as it shows the decrease of transmittance of 0.4% or smaller, preferably 0.2% or smaller to a wavelength of 157 nm per 10-millimeter thickness. However, this standard for the non-defective crystal is for illustrative purposes only, and types of the irradiated energy rays and irradiation conditions are not limited to the above. Of course, the decrease of transmittance is not limited to the above valve. The best standard for the non-defective crystal can be set according to specifications required for CaF₂ crystal.

The oxidation and remaining scavenger both would lower the transmittance and laser durability. More specifically, it is known that the oxidation greatly lowers the transmittance but does not lower the laser durability so much. On the other hand, the remaining scavenger does not lower the transmittance so much, but greatly lowers the laser durability. Therefore, the evaluation of the decrease of transmittance through an irradiation of a high-energy ray can detect the remaining scavenger at higher sensitivity than the evaluation of transmittance described in Example 2.

Thus, the above process control over grown crystal evaluates the decrease of transmittance through an irradiation of a high-energy ray, and stably manufactures crystal having excellent qualities, such as internal transmittance and laser durability.

### EXAMPLE 5

A description will now be given of an example 5 characterized in that process control means evaluates fluorescent light emitted from CaF₂ crystal in response to an UV irradiation.

A material CM as CaF₂ powder was mixed with scavenger, and purified into a purified article in the purification furnace 100 shown in FIG. 1 by melting the material at a high temperature and then cooling the same. An end of the purified article was partially crushed and taken out as a cleavage article having a thickness of about 10 mm.

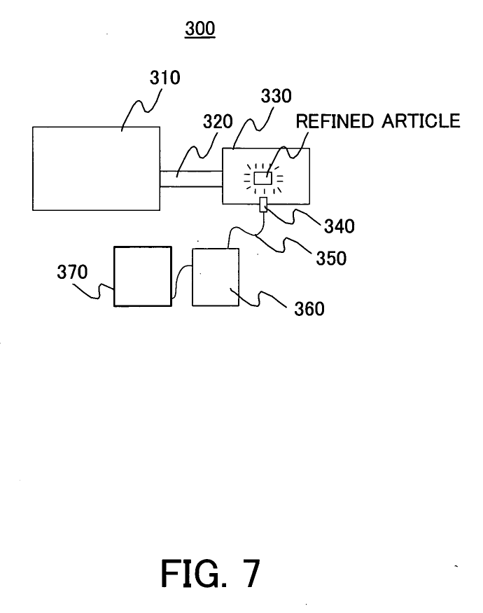

Next, a fluorescent measuring apparatus 300 shown in FIG. 7 was used to measure fluorescent light emitted from the cleavage article or purified article while F₂ laser having an energy density of 10 mJ/cm² per pulse is irradiated onto the article. FIG. 7 is an exemplary schematic block diagram of the fluorescent measuring apparatus 300 that measures the fluorescent light emitted from CaF₂ crystal in response to UV irradiations.

In the fluorescent measuring apparatus 300, 310 is a light source for irradiating the UV light, such as F₂ laser, and irradiates F₂ laser via a beam shaping optical system 320 onto a purified article installed in a chamber 330. The fluorescent light emitted from the purified article in response to the irradiation of F₂ laser reaches a spectrometer part 360 via a light-receiving probe 340 and an optical fiber 350, and the spectrometer part 360 measures the fluorescent wavelength spectrum. The measured wavelength spectrum is sent to a controller 370 for time quadrature, and the fluorescent intensity is obtained for each wavelength.

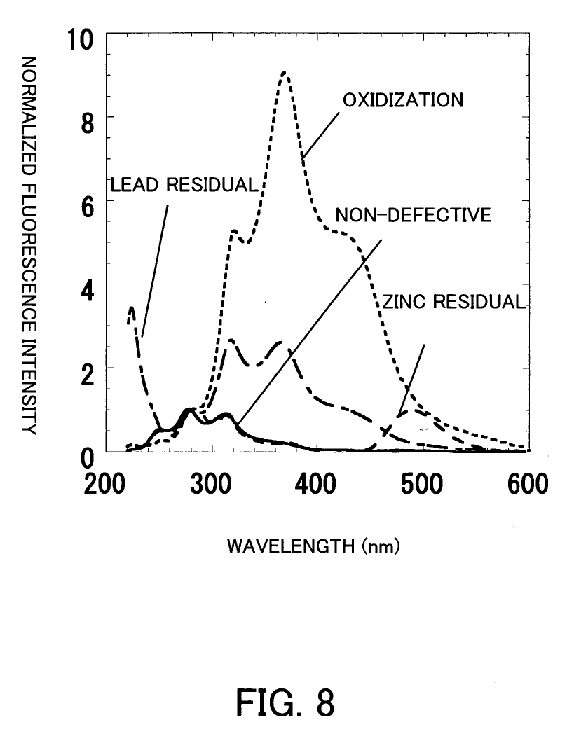

FIG. 8 shows an exemplary measurement result of fluorescent light emitted from the cleavage article in response to the F₂ laser, where an abscissa axis is a wavelength between 200 nm and 600 nm, and an ordinate axis is the normalized fluorescent intensity by setting the fluorescent intensity to a wavelength of 280 nm as a peak intrinsic to the CaF₂ crystal to be 1.

Referring to FIG. 8, the oxidized purified article has higher fluorescent intensity than the non-defective purified article at wavelengths of 320 nm and 370 nm. On the other hand, when lead or zinc in lead fluoride or zinc fluoride as scavenger remains, the high fluorescent intensity appears at the wavelengths of 225 nm or 490 nm.

Thus, the purified article that oxides or remains scavenger can be determined to be defective based on the fluorescent light. When the purified article that oxides or remains scavenger is used for the next growth step, the grown crystal succeeds the property of the purification step and does not provide a good result. It is important for the process control to select the non-defective purified article and use only the selected non-defective purified article for the growth step. An applied standard normalizes by setting the fluorescent intensity to the wavelength of 280 nm to be 1 in response to F₂ laser having an energy density of 10 mJ/cm² per pulse, and considers a purified article to be non-defective as far as it shows fluorescent relative intensity of 5 or smaller to wavelengths of 320 nm and 370 nm, 2 or smaller to a wavelength of 225 nm, and 1 or smaller to a wavelength of 490 nm. However, this standard for the non-defective article is for illustrative purposes only, and the types and irradiation conditions of the irradiated UV light are not limited to the above. Of course, the fluorescent relative intensity is not limited to the above value, and the best standard for the non-defective article can be set according to specifications required for CaF₂ crystal.

Thus, the above process control over purified articles evaluates UV-induced fluorescent light, and stably manufactures crystal having excellent qualities, such as internal transmittance and laser durability.

### EXAMPLE 6

A description will now be given of an example 6 characterized in that process control means evaluates fluorescent light emitted from CaF₂ crystal in response to an UV irradiation.

A block of purified article RM was mixed with scavenger, and subject to a crystal growth in the crystal growth furnace 200 shown in FIG. 3. Single crystal grew gradually as the crucible 210 went down to cool after the purified article RM was melted at a high temperature. The grown single crystal was taken out of the crucible 210, cut into a cylinder having a thickness of 50 mm, and polished at both surfaces thereof.

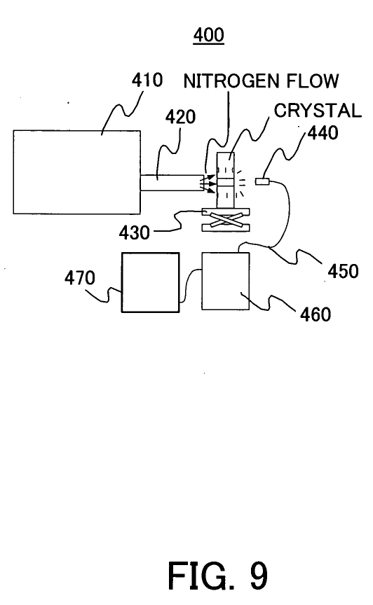

Next, a fluorescent measuring apparatus 400 shown in FIG. 9 was used to measure the fluorescent light while F₂ laser having an energy density of 10 mJ/cm² per pulse was irradiated onto five points in crystal including four peripheral points and one center point in the crystal. FIG. 9 is a schematic block diagram of the fluorescent measuring apparatus 400.

In the fluorescent measuring apparatus 400, 410 is a light source for irradiating UV light, such as F₂ laser, and irradiates F₂ laser through a beam shaping optical system 420 onto crystal installed in a stage 430. The positions on the crystal, onto which the F₂ laser is irradiated, (i.e., four peripheral points and one center point) are adjustable by driving the stage 430. The fluorescent light emitted from the crystal in response to the irradiations of the F₂ laser reaches a spectrometer part 460 via a light-receiving probe 440 and an optical fiber 450, and the spectrometer part 460 measures the fluorescent wavelength spectrum. The measured wavelength spectrum is sent to the controller 470 for time quadrature, and the fluorescent intensity is obtained for each wavelength.

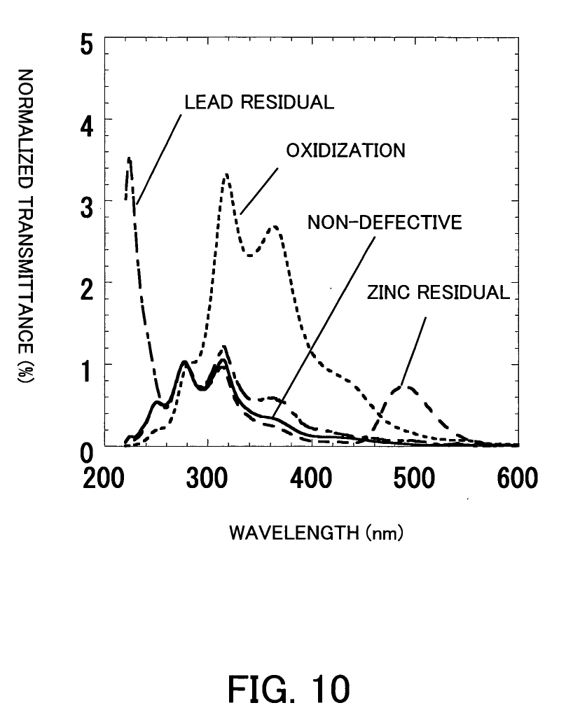

FIG. 10 shows an exemplary measurement result of fluorescent light emitted from the crystal in response to irradiations of the F₂ laser, where an abscissa axis is a wavelength between 200 nm and 600 nm, and an ordinate axis is the normalized fluorescent intensity by setting the fluorescent intensity for a wavelength of 280 nm as a peak peculiar to the CaF₂ crystal to be 1. Each measurement result picks up the highest fluorescent intensity of one of five measurement points that includes four peripheral points and one center point in the crystal.

Referring to FIG. 10, the oxidized purified article has higher fluorescent intensity than the non-defective purified article at wavelengths of 320 nm and 370 nm. On the other hand, when lead or zinc in lead fluoride or zinc fluoride as scavenger remains, the high fluorescent intensity appears at the wavelengths of 225 nm or 490 nm.

Thus, the crystal that oxides or remains scavenger can be determined to be defective based on the fluorescent light. When the crystal that oxides or remains scavenger is used for the next annealing step, the annealing step cannot improve the transmittance and cannot provide crystal having excellent qualities, such as internal transmittance and laser durability. Therefore, it is important for the process control to select the non-defective crystal and use only the selected non-defective crystal for the annealing step. An applied standard normalizes by setting the fluorescent intensity to the wavelength of 280 nm to be 1 in response to F₂ laser having an energy density of 10 mJ/cm² per pulse, and considers crystal to be non-defective as far as it shows fluorescent relative intensity of 3 or smaller to the wavelengths of 320 nm and 370 nm, 1 or smaller to the wavelength of 225 nm, and 0.5 or smaller to the wavelength of 490 nm. However, this standard for the non-defective article is for illustrative purposes only, and the types and irradiation conditions of the irradiated UV light are not limited to the above. Of course, the fluorescent relative intensity is not limited to the above value, and the best standard for the non-defective article can be set according to specifications required for CaF₂ crystal.

Thus, the above process control over purified articles evaluates UV-induced fluorescent light, and stably manufactures crystal having excellent qualities, such as internal transmittance and laser durability.

An optical element is made from CaF₂ crystal obtained from the inventive crystallization method. The optical element may include, for example, a lens, a diffraction optical element, an optical film, and a combination thereof. For example, it may include a lens, a multi-lens, a lens array, a lenticule lens, a fly-eye lens, an aspheric lens, a diffraction grating, a binary optics element and a combination thereof. The optical element includes, for example, an optical sensor (e.g., for use with focus control) in addition to a single lens. If necessary, an anti-reflection coating may be provided on an optical element made of CaF₂ crystal. The anti-reflection coating is suitably made, for example, of magnesium fluoride, aluminum oxide, and tantalum oxide, by resistance heating vapor deposition, electron beam vapor deposition, sputtering, etc. The optical element obtained by the present invention has excellent qualities, such as internal transmittance and laser durability, and thus exhibits more improved optical performance than the conventional optical elements.

A projection optical system and an illumination optical system suitable for ArF excimer laser and F₂ laser can be made of a combination of various inventive optical elements. An exposure apparatus for photolithography can include a laser light source, an optical system that includes CaF₂ lens(es) obtained by the inventive crystallization method, and a stage for driving a wafer.

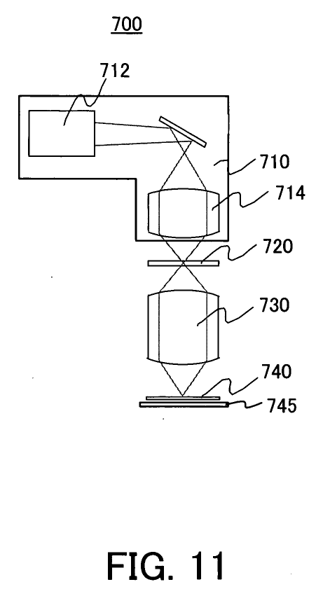

Referring now to FIG. 11, a description will be given of the exposure apparatus 700. Here, FIG. 11 is a schematic block diagram of the exposure apparatus 700. The exposure apparatus 700 includes, as shown in FIG. 11, an illumination apparatus 710 for illuminating a reticle 720 which forms a circuit pattern, a projection optical system 730 that projects diffracted light created from the illuminated mask pattern onto a plate 740, and a stage 745 for supporting the plate 740.

The exposure apparatus 700 is a projection exposure apparatus that exposes onto the plate 740 a circuit pattern created on the reticle 720, e.g., in a step-and-repeat or a step-and-scan manner. Such an exposure apparatus is suitable for a sub-micron or quarter-micron lithography process, and this embodiment exemplarily describes a step-and-scan exposure apparatus (which is also called “a scanner”). The “step-and-scan manner”, as used herein, is an exposure method that exposes a mask pattern onto a wafer by continuously scanning the wafer relative to the mask, and by moving, after a shot of exposure, the wafer stepwise to the next exposure area to be shot. The “step-and-repeat manner” is another mode of exposure method that moves a wafer stepwise to an exposure area for the next shot every shot of cell projection.

The illumination apparatus 710 illuminates the reticle 720 which forms a circuit pattern to be transferred, and includes a light source unit 712 and an illumination optical system 714.

The light source unit 712 uses as a light source, for example, as ArF excimer laser with a wavelength of approximately 193 nm, and a KrF excimer laser with a wavelength of approximately 248 nm, but the a type of laser is not limited to excimer laser and, for example, F₂ laser with a wavelength of approximately 157 nm and a YAG laser may be used. Similarly, the number of laser units is not limited. For example, two independently acting solid lasers would cause no coherence between these solid lasers and significantly reduces speckles resulting from the coherence. An optical system for reducing speckles may swing linearly or rotationally. When the light source unit 712 uses laser, it is desirable to employ a beam shaping optical system that shapes a parallel beam from a laser source to a desired beam shape, and an incoherently turning optical system that turns a coherent laser beam into an incoherent one. A light source applicable to the light source unit 712 is not limited to a laser, and may use one or more lamps such as a mercury lamp and a xenon lamp.

The illumination optical system 714 is an optical system that illuminates the reticle 720, and includes a lens, a mirror, a light integrator, a stop, and the like, for example, a condenser lens, a fly-eye lens, an aperture stop, a condenser lens, a slit, and an image-forming optical system in this order. The illumination optical system 714 can use any light whether it is axial or non-axial light. The light integrator may include a fly-eye lens or an integrator formed by stacking two sets of cylindrical lens array plates (or lenticular lenses), and be replaced with an optical rod or a diffractive element. An optical element made of inventive CaF₂ crystal is applicable to an optical element, such as a lens in the illumination optical system 714.

The reticle 720 is made, for example, of quartz, forms a circuit pattern (or an image) to be transferred, and is supported and driven by a mask stage (not shown). Diffracted light emitted from the reticle 720 passes the projection optical system 730, thus and then is projected onto the plate 740. The reticle 720 and the plate 740 are located in an optically conjugate relationship. Since the exposure apparatus 200 of this embodiment is a scanner, the reticle 720 and the plate 740 are scanned at the speed ratio of the reduction ratio of the projection optical system 730, thus transferring the pattern on the reticle 720 to the plate 740. If it is a step-and-repeat exposure apparatus (referred to as a “stepper”), the reticle 720 and the plate 740 stand still in exposing the mask pattern.

The projection optical system 730 is an optical system that projects light that reflects a pattern on the reticle 720 located on an object surface onto the plate 740 located on an image surface. The projection optical system 730 may use an optical system solely including a plurality of lens elements, an optical system including a plurality of lens elements and at least one concave mirror (a catadioptric optical system), an optical system including a plurality of lens elements and at least one diffractive optical element such as a kinoform, and a full mirror type optical system, and so on. Any necessary correction of the chromatic aberration may use a plurality of lens units made from glass materials having different dispersion values (Abbe values), or arrange a diffractive optical element such that it disperses in a direction opposite to that of the lens unit. An optical element made of inventive CaF₂ crystal is applicable to an optical element, such as a lens in the projection optical system 730.

The plate 740 is an exemplary object to be exposed, such as a wafer and a LCD, and photoresist is applied to the plate 740. A photoresist application step includes a pretreatment, an adhesion accelerator application treatment, a photo-resist application treatment, and a pre-bake treatment. The pretreatment includes cleaning, drying, etc. The adhesion accelerator application treatment is a surface reforming process so as to enhance the adhesion between the photoresist and a base (i.e., a process to increase the hydrophobicity by applying a surface active agent), through a coat or vaporous process using an organic coating such as HMDS (Hexamethyl-disilazane). The pre-bake treatment is a baking (or burning) step, softer than that after development, which removes the solvent.

The stage 745 supports the plate 740. The stage 745 may use any structure known in the art, and a detailed description of its structure and operation is omitted. The stage 745 may use, for example, a linear motor to move the plate 740 in XY directions. The reticle 720 and plate 740 are, for example, scanned synchronously, and the positions of the stage 745 and a mask stage (not shown) are monitored, for example, by a laser interferometer and the like, so that both are driven at a constant speed ratio. The stage 745 is installed on a stage stool supported on the floor and the like, for example, via a damper, and the mask stage and the projection optical system 730 are installed on a lens barrel stool (not shown) supported, for example, via a damper to the base frame placed on the floor.

In exposure, light emitted from the light source 712, e.g., Koehler-illuminates the reticle 720 via the illumination optical system 714. Light that passes through the reticle 720 and reflects the mask pattern is imaged onto the plate 740 by the projection optical system 730. The illumination and projection optical systems 714 and 730 in the exposure apparatus 700 include an optical element made of inventive CaF₂ crystal that transmits the UV light, FUV light, and VUV light with high transmittance, and provide high-quality devices (such as semiconductor devices, LCD devices, photographing devices (such as CCDs, etc.), thin film magnetic heads, and the like) with high throughput and economic efficiency.

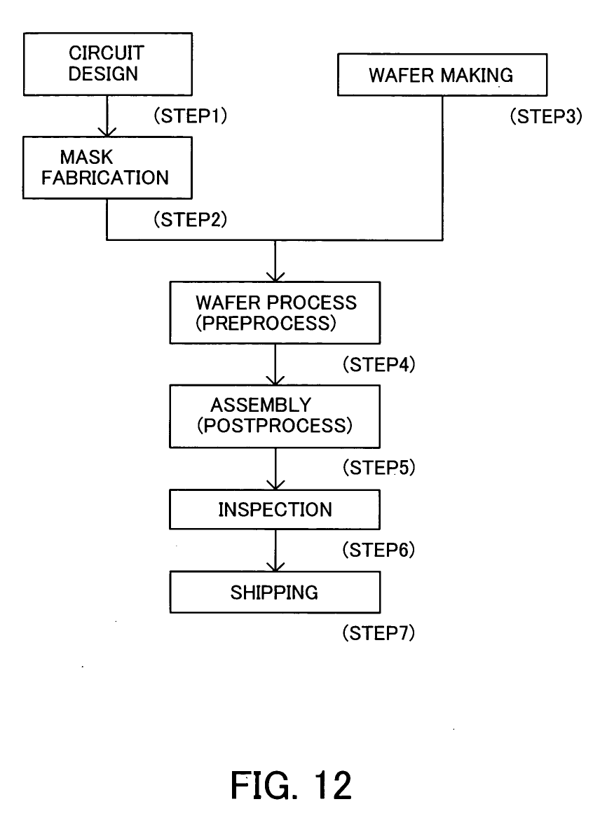

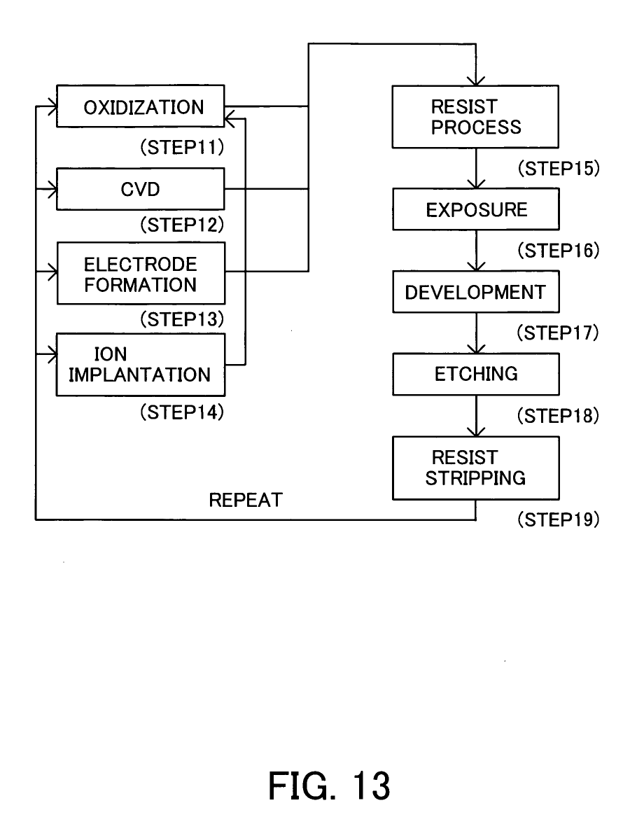

Referring now to FIGS. 12 and 13, a description will be given of an embodiment of a device fabrication method using the above mentioned exposure apparatus 700.

FIG. 12 is a flowchart for explaining how to fabricate devices (i.e., semiconductor chips such as IC and LSI, LCDs, CCDs, and the like). Here, a description will be given of the fabrication of a semiconductor chip as an example. Step 1 (circuit design) designs a semiconductor device circuit. Step 2 (mask fabrication) forms a mask having a designed circuit pattern. Step 3 (wafer making) manufactures a wafer using materials such as silicon. Step 4 (wafer process), which is also referred to as a pretreatment, forms actual circuitry on the wafer through lithography using the mask and wafer. Step 5 (assembly), which is also referred to as a post-treatment, forms into a semiconductor chip the wafer formed in Step 4 and includes an assembly step (e.g., dicing, bonding), a packaging step (chip sealing), and the like. Step 6 (inspection) performs various tests for the semiconductor device made in Step 5, such as a validity test and a durability test. Through these steps, a semiconductor device is finished and shipped (Step 7).

FIG. 13 is a detailed flowchart of the wafer process in Step 4. Step 11 (oxidation) oxidizes the wafer's surface. Step 12 (CVD) forms an insulating layer on the wafer's surface. Step 13 (electrode formation) forms electrodes on the wafer by vapor disposition and the like. Step 14 (ion implantation) implants ion into the wafer. Step 15 (resist process) applies a photosensitive material onto the wafer. Step 16 (exposure) uses the exposure apparatus 700 to expose a circuit pattern on the mask onto the wafer. Step 17 (development) develops the exposed wafer. Step 18 (etching) etches parts other than a developed resist image. Step 19 (resist stripping) removes disused resist after etching. These steps are repeated, and multi-layer circuit patterns are formed on the wafer. Use of the fabrication method in this embodiment helps fabricate higher-quality devices than conventional. Thus, the device fabrication method using the processing system 100 (or the exposure apparatus 200), and resultant devices constitute one aspect of the present invention.

Further, the present invention is not limited to these preferred embodiments and various variations and modifications may be made without departing from the scope of the present invention. For example, the crystallization process can combine above process control means, and provides the process control between the purification step and the growth step, and between the growth step and the annealing step. A cooling method to cooling a melted material can use various methods, in addition to a crucible descending method, such as a method that fixes the crucible and ascends the heater, a method that powers down the heater output, and any other known method.

Thus, the present invention provides a crystallization method, which can stably manufacture crystal having excellent qualities, such as internal transmittance and laser durability.

What is claimed is:

1. A crystallization method comprising the steps of:
producing a purified article made of a material as crystalloid by mixing with scavenger, melting, and then solidifying the material;
inspecting an amount of remaining oxygen contained in the purified article; and
melting the purified article selected by said inspecting step, and then growing crystal from the purified article.

2. A crystallization method according to claim 1, wherein the crystalloid is calcium fluoride.

3. A crystallization method comprising the steps of:
producing a purified article made of a material as crystalloid by mixing with scavenger, melting, and then solidifying the material;
measuring transmittance in the purified article produced by said producing step to a predetermined wavelength, and selecting the purified article having predetermined transmittance; and
melting the purified article having the predetermined transmittance selected by said selecting step, and then growing crystal from the purified article.

4. A crystallization method according to claim 3, wherein the predetermined wavelength is between 100 nm and 300 nm.

5. A crystallization method according to claim 3, wherein the predetermined transmittance is 80% is greater per 10-millimeter thickness when normalized by setting transmittance to light having a wavelength of 200 nm to be 100%.

6. A crystallization method comprising the steps of:
producing a purified article made of a material as crystalloid by mixing with scavenger, melting, and then solidifying the material;
measuring a decrease of transmittance in the purified article produced by said producing step after irradiating a predetermined energy ray onto the purified article, and selecting the purified article that has the decrease of transmittance in a predetermined range; and
melting the purified article having the predetermined transmittance selected by said selecting step, and then growing crystal from the purified article.

7. A crystallization method according to claim 6, wherein the predetermined energy ray is F₂ laser or ArF excimer laser.

8. A crystallization method according to claim 6, wherein the predetermined energy ray is X-ray or γ-ray.

9. A crystallization method according to claim 6, wherein the decrease of transmittance within the predetermined range is 2% or smaller per 10-millimeter thickness in a wave range between 150 nm and 800 nm when F₂ laser having an energy density of 10 mJ/cm² per pulse is irradiated with 10⁵ pulses or greater.

10. A crystallization method according to claim 6, wherein the decrease of transmittance within the predetermined range is 10% or smaller per 10-millimeter thickness in a wave range between 200 nm and 900 nm when γ-ray of 10⁵ R /hour is irradiated for one hour.

11. A crystallization method comprising the steps of:
producing a purified article made of a material as crystalloid by mixing with scavenger, melting, and then solidifying the material;
measuring fluorescent intensity emitted from the purified article produced by said producing step after irradiating ultraviolet light onto the purified article, and selecting the purified article that has predetermined fluorescent intensity; and
melting the purified article having the predetermined fluorescent intensity selected by said inspecting step, and then growing crystal from the purified article.

12. A crystallization method according to claim 11, wherein the ultraviolet light is F₂ laser or ArF excimer laser.

13. A crystallization method according to claim 11, wherein the predetermined fluorescent intensity is relative intensity of 5 or smaller to fluorescent light having a wavelength of 370 nm, relative intensity of 2 or smaller to fluorescent light having a wavelength of 225 nm, and relative intensity of 1 or smaller to fluorescent light having a wavelength of 490 nm, where normalized by setting intensity of fluorescent light which has a wavelength of 280 nm to be 1 when F₂ laser having an energy density of 10 mJ/cm² per pulse is irradiated.

14. A crystallization method comprising the steps of:
melting a purified article produced from a material as crystalloid, and then growing crystal made of the material;
inspecting an amount of remaining oxygen contained in the crystal grown in said growing step; and
gradually cooling the crystal after the crystal selected by said inspecting step is processed at high temperature above 1000° C.

15. A crystallization method comprising the steps of:
melting a purified article produced from a material as crystalloid, and then growing crystal made of the material;
measuring transmittance in the crystal grown by said growing step to a predetermined wavelength, and selecting the crystal having predetermined transmittance; and
gradually cooling the crystal after the crystal having the predetermined transmittance selected by said selecting step is processed at high temperature 1000° C.

16. A crystallization method comprising the steps of:
melting a purified article produced from a material as crystalloid, and then growing crystal made of the material;
measuring a decrease of transmittance in the crystal after irradiating a predetermined energy ray onto the crystal grown by said growing step, and selecting the crystal having the decrease of transmittance in a predetermined range; and
gradually cooling the crystal after the crystal having the predetermined transmittance selected by said inspecting step is processed at high temperature above 1000° C.

17. A crystallization method comprising the steps of:
melting a purified article produced from a material as crystalloid, and then growing crystal made of the material;
measuring fluorescent intensity emitted from the crystal grown by said growing step after irradiating ultraviolet onto the crystal, and selecting the crystal having the predetermined fluorescent intensity; and
gradually cooling the crystal after the crystal having the predetermined transmittance selected by said selecting step is processed at high temperature above 1000° C.

18. An optical element made of a single crystal, said single crystal being manufactured by a crystallization method that includes the steps of producing a purified article made of a material as crystalloid by mixing with scavenger, melting, and then solidifying the material, inspecting an amount of remaining oxygen contained in the purified article, and melting the purified article selected by the inspecting step, and then growing crystal from the purified article.

19. An optical element according to claim 18, wherein said optical element is a lens, a diffraction grating, an optical film or a combination thereof.

20. An exposure apparatus comprising an optical system that includes an optical element made of single crystal, said single crystal being manufactured by a crystallization method that includes the steps of producing a purified article made of a material as crystalloid by mixing with scavenger, melting, and then solidifying the material, inspecting an amount of remaining oxygen contained in the purified article, and melting the purified article selected by the inspecting step, and then growing crystal from the purified article.

21. A device fabrication method comprising the steps of:
exposing an object using an exposure apparatus; and
developing the object that has been exposed, wherein said exposure apparatus comprises an optical system that includes an optical element made of single crystal, said single crystal being manufactured by a crystallization method includes the steps of producing a purified article made of a material as crystalloid by mixing with scavenger, melting, and then solidifying the material, inspecting an amount of remaining oxygen contained in the purified article, and melting the purified article selected by the inspecting step, and then growing crystal from the purified article.

22. A device fabrication method according to claim 21, wherein said exposing step irradiates onto the object exposure light that is selected from ultraviolet light, far ultraviolet light, and vacuum ultraviolet light.
